(19) United States
(12) Patent Application Publication
(10) Pub. No.: US 2022/0301337 A1
(43) Pub. Date: Sep. 22, 2022

(54) FINGERPRINT SENSING MODULE AND ELECTRONIC DEVICE

(71) Applicants: YU-KUO CHENG, Taipei City (TW); Egis Technology Inc., Hsinchu City (TW)

(72) Inventors: Yu-Hsiang Huang, Hsinchu City (TW); Chen-Chih Fan, Hsinchu City (TW); Yu-Kuo Cheng, Taipei City (TW); Bruce C. S. Chou, Hsinchu City (TW)

(73) Assignees: YU-KUO CHENG, Taipei City (TW); Egis Technology Inc., Hsinchu City (TW)

(21) Appl. No.: 17/639,586

(22) PCT Filed: Apr. 29, 2020
(86) PCT No.: PCT/CN2020/087764

§ 371 Date: Mar. 2, 2022

Related U.S. Application Data
(60) Provisional application No. 62/903,927, filed on Sep. 22, 2019.
(60) Provisional application No. 62/910,472, filed on Oct. 4, 2019.

(51) Int. Cl. G06V 40/13; G06F 3/042; H01L 27/146; H01L 27/32

(52) U.S. Cl. CPC G06V 40/1324; G06V 40/1318; G06F 3/0421; H01L 27/14623; H01L 27/14627; H01L 27/323

(57) ABSTRACT

A fingerprint sensing module suitable for receiving a sensing light beam and an electronic device is provided. The fingerprint sensing module includes a sensing element, a light transmitting layer disposed on the sensing element, a micro-lens layer disposed on the light transmitting layer, and a first light shielding layer disposed in the light transmitting layer and including multiple first openings arranged in an array. Positions of the first openings in odd-numbered rows are the same, and those in even-numbered rows are the same. Positions the first openings in the odd-numbered rows are different from those in the even-numbered rows. A sensing light beam includes multiple first light beams incident to a part of a sensing unit in a first transmission direction and multiple second light beams incident to another part of the sensing unit in a second transmission direction. The first transmission direction is different from the second transmission direction.

### BACKGROUND

### Technology Field

The invention relates to a sensing module, and particularly, to a fingerprint sensing module and an electronic device.

### Description of Related Art

As portable electronic devices (e.g., smart phones or tablet computers) have developments in implementing a large screen-to-body ratio or a full-screen display, capacitive fingerprint sensing modules conventionally located beside a screen can no longer be disposed on the front of an electronic device. Therefore, a solution of configuring a capacitive fingerprint sensing module on a side or a back of the electronic device is adopted. However, configuring the capacitive fingerprint sensing module on the side or the back has its inconvenience in use, so an optical fingerprint sensing module disposed under the screen has been developed recently.

Generally speaking, the sensing area of the fingerprint sensing module is proportional to the size of the fingerprint sensing module. In some methods, to increase the sensing area of the fingerprint sensing module, the fingerprint sensing module is designed to adaptively receive obliquely incident light, so as to increase the sensing area of the fingerprint sensing module. However, such a method requires an angle design for different pixels in the fingerprint sensing module according to different positions, thereby forming a gradient structure. Therefore, this method may increase the difficulty in manufacturing, and the optical paths passing through each pixel vary, so the optical path difference may be generated between the sensing light of pixels at different positions, thereby resulting in the distortion of the sensing image.

### SUMMARY

The invention is for a fingerprint sensing module and an electronic device, which are capable of increasing the sensing area and have good optical sensing quality.

The invention provides a fingerprint sensing module suitable for receiving a sensing light beam. The fingerprint sensing module includes a sensing element, a light transmitting layer, a micro-lens layer, and a first light shielding layer. The light transmitting layer is disposed on the sensing element. The micro-lens layer is disposed on the light transmitting layer. The first light shielding layer is disposed in the light transmitting layer and includes a plurality of first openings arranged in an array. Positions of the first openings in odd-numbered rows are the same, positions of the first openings in even-numbered rows are the same, and the positions of the first openings in the odd-numbered rows are different from the positions of the first openings in the even-numbered rows. The sensing light beam includes a plurality of first light beams and a plurality of second light beams. The first light beams are incident to at least a part of the sensing units in a first transmission direction, the second light beams are incident to at least another part of the sensing units in a second transmission direction, and the first transmission direction is different from the second transmission direction.

The invention provides a fingerprint sensing module suitable for receiving a sensing light beam and including a sensing element, a light transmitting layer, a micro-lens layer, and a first light shielding layer. The sensing element includes a plurality of sensing units arranged in an array. The light transmitting layer is disposed on the sensing element. The micro-lens layer is disposed on the light transmitting layer and includes a plurality of micro-lenses arranged in an array. The first light shielding layer is disposed in the light transmitting layer and includes a plurality of first openings arranged in an array. Positions of the first openings in odd-numbered rows are the same, positions of the first openings in even-numbered rows are the same, and the positions of the first openings in the odd-numbered rows are different from the positions of the first openings in the even-numbered rows. The sensing light beam includes a plurality of first light beams and a plurality of second light beams. The first light beams are incident to at least a part of the sensing units in a first transmission direction, the second light beams are incident to at least another part of the sensing units in a second transmission direction, and the first transmission direction is different from the second transmission direction.

The invention further provides an electronic device including a display panel and a fingerprint sensing module. The display panel is suitable for providing an illumination light beam to a finger to reflect a sensing light beam. The fingerprint sensing module is disposed below the display panel and is suitable for sensing the sensing light beam reflected by the finger. The fingerprint sensing module includes a sensing element, a light transmitting layer, a micro-lens layer, and a first light shielding layer. The sensing element includes a plurality of sensing units arranged in an array. The light transmitting layer is disposed on the sensing element. The micro-lens layer is disposed on the light transmitting layer and includes a plurality of micro-lenses arranged in an array. The first light shielding layer is disposed in the light transmitting layer and includes a plurality of first openings arranged in an array. Positions of the first openings in odd-numbered rows are the same, positions of the first openings in even-numbered rows are the same, and the positions of the first openings in the odd-numbered rows are different from the positions of the first openings in the even-numbered rows. The sensing light beam includes a plurality of first light beams and a plurality of second light beams. The first light beams are incident to at least a part of the sensing units in a first transmission direction, the second light beams are incident to at least another part of the sensing units in a second transmission direction, and the first transmission direction is different from the second transmission direction.

In summary, in the fingerprint sensing module and the electronic device of the invention, the first light shielding layer disposed in the light transmitting layer includes multiple first openings, and the positions of the first openings in the odd-numbered rows are different from the positions of the first openings in the even-numbered rows. Therefore, a part of the sensing light beam may be allowed to be incident to the sensing element in the first transmission direction, and another part of the sensing light beam can be incident to the sensing element in the second transmission direction. Accordingly, the sensing area may be increased, the difficulty in manufacturing may be reduced, and the optical path difference may be prevented to improve the good optical sensing quality.

### BRIEF DESCRIPTION OF THE DRAWING

FIG. 1 is a schematic view of an electronic device according to an embodiment of the invention.

FIG. 2 is a schematic view of an enlarged area A of the electronic device of FIG. 1.

FIG. 3 is a schematic top view of a fingerprint sensing module according to an embodiment of the invention.

FIG. 4A and FIG. 4B are schematic cross-sectional views of the fingerprint sensing module of FIG. 3 taken along lines BB′ and CC′, respectively.

FIG. 5 is a schematic view of a sensing area of the fingerprint sensing module of FIG. 3.

FIG. 6 is a schematic top view of a fingerprint sensing module according to another embodiment of the invention.

FIG. 7 is a schematic view of a sensing area of the fingerprint sensing module of FIG. 6.

### DESCRIPTION OF REFERENCE NUMERALS

10: electronic device

20: finger

50: display panel

52: fingerprint sensing region

100, 100A: fingerprint sensing module

110: sensing element

112: sensing unit

120: light transmitting layer

130: micro-lens layer

132: micro-lens

140: first shielding layer

150: second shielding layer

160: filter layer

D, P, X, Y: width

D1: first transmission direction

D2: second transmission direction

E1: odd-numbered row

E2: even-numbered row

F1: odd-numbered column

F2: even-numbered column

H, h: distance

θ: incident angle

L1: illumination light beam

L2: sensing light beam

L21: first light beam

L22: second light beam

L31: first critical light beam

L32: second critical light beam

O1: first opening

O2: second opening

### Description of the Embodiments

Reference will now be made in detail to the exemplary embodiments of the invention, examples of which are illustrated in the accompanying drawings. Whenever possible, the same reference numerals are used to represent the same or similar parts in the accompanying drawings and description.

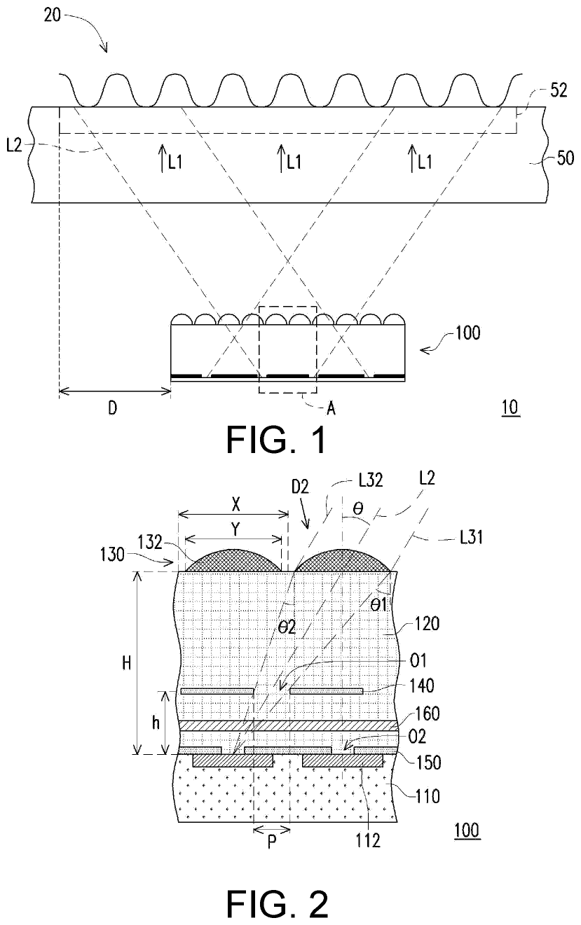

FIG. 1 is a schematic view of an electronic device according to an embodiment of the invention. Referring to FIG. 1, in the embodiment, an electronic device 10 is provided and adapted for sensing biometric information of a finger 20, such as a fingerprint, by sending out. The electronic device 10 includes a display panel 50 and a fingerprint sensing module 100. The display panel 50 is adapted to provide an illumination light beam L1 to the finger 20 to reflect a sensing light beam L2. The display panel 50 is an organic light-emitting diode (OLED) display panel, for example. However, in other embodiments, the display panel 50 may also be a liquid crystal display panel or other suitable display panels.

The fingerprint sensing module 100 is disposed below the display panel 50 and is suitable for sensing the sensing light beam L2 reflected by the finger 20. That is, the sensing light beam L2 carries fingerprint signals. Specifically, a user can place the finger 20 on a fingerprint sensing region 52 of the display panel 50, and the sensing light beam L2 reflected by the finger 20 penetrates the display panel 50 and is transmitted to the fingerprint sensing module 100. In the embodiment, the display panel 50 is a transparent display panel, for example. However, in other embodiments, the display panel 50 may also be a display panel having a light-transmitting opening in the area above the fingerprint sensing module 100. For example, the electronic device 10 is a mobile phone, a tablet computer, a laptop computer, or other suitable electronic devices.

FIG. 2 is a schematic view of an enlarged area A of the electronic device of FIG. 1. Referring to both FIG. 1 and FIG. 2, the fingerprint sensing module 100 includes a sensing element 110, a light transmitting layer 120, a micro-lens layer 130, and a first light shielding layer 140. The sensing element 110 includes multiple sensing units 112 arranged in an array. In the embodiment, for example, the sensing element 110 is a light sensor, such as a complementary metal oxide semiconductor (CMOS) or a charge coupled device (CCD), and the sensing unit 112 is a sensing pixel in the light sensor. The sensing unit 112 of the sensing element 110 is adapted to receive the sensing light beam L2 for conversion into an electrical signal. The light transmitting layer 120 is disposed on the sensing element 110 and is adapted for transmitting the sensing light beam L2 to pass therethrough. In addition, by performing the manufacturing process, other structures can be configured in the unfinished light transmitting layer 120 when the light transmitting layer 120 is fabricated, so that the configured structures, such as a light shielding layer, a filter layer, or other types of structures in the subsequent description paragraphs, can be fixed at a specific height or position in the light transmitting layer 120, but the invention is not limited thereto. The micro-lens layer 130 is disposed on the light transmitting layer 120 and includes multiple micro-lenses 132 arranged in an array. In the embodiment, the centerline of the micro-lenses 132 is aligned with the centerline of the sensing units 112, but the invention is not limited thereto.

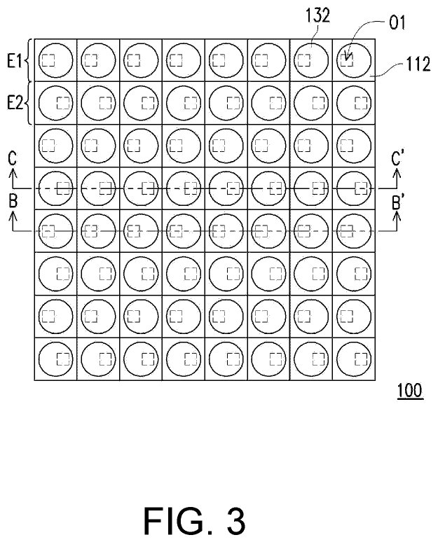

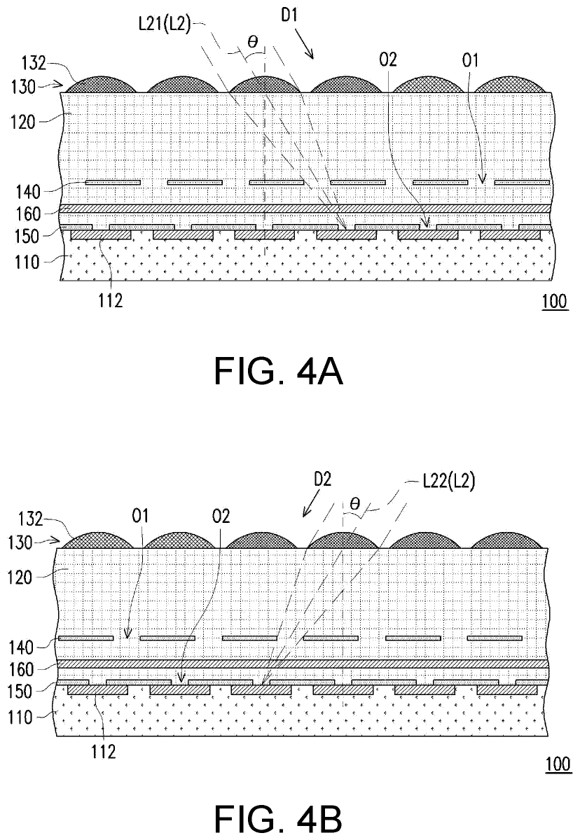

FIG. 3 is a schematic top view of a fingerprint sensing module according to an embodiment of the invention. FIG. 4A and FIG. 4B are schematic cross-sectional views of the fingerprint sensing module of FIG. 3 taken along lines BB′ and CC′, respectively. Referring to FIG. 3 to FIG. 4B altogether, the first light shielding layer 140 is disposed in the light transmitting layer 120 and includes multiple first openings O1 arranged in an array. The positions of the first openings O1 in odd-numbered rows E1 are shifted toward one side of the corresponding sensing units 112, for example, shifted to the left in FIG. 3, and the positions of the first openings O1 in even-numbered rows E2 are shifted toward another side of the corresponding sensing units 112, for example, shifted to the right in FIG. 3. Therefore, the positions of the first openings O1 in the odd-numbered rows E1 and the positions of the first openings O1 in the even-numbered rows E2 are shifted toward different directions of the corresponding sensing units 112, respectively. Specifically, in the embodiment, the positions of the first openings O1 in the odd-numbered rows E1 and the corresponding sensing units 112 are disposed in a staggered manner, as shown in FIG. 3 and FIG. 4A. Accordingly, a part of the sensing light beam L2 is incident to the corresponding sensing unit 112 at a tilt angle (e.g., from left to right). On the other hand, the positions of the first openings O1 in the even-numbered rows E2 and the corresponding sensing units 112 are similarly disposed in a staggered manner, as shown in FIG. 3 and FIG. 4B. Accordingly, the sensing light beam L2 at another tilt angle (e.g., from right to left) is incident to the corresponding sensing unit 112.

That is, the sensing light beam L2 includes multiple first light beams L21 and multiple second light beams L22. The first light beam L21 is incident to at least a part of the sensing units 112 in a first transmission direction D1, the second light beam L22 is incident to another part of the sensing units 112 in a second transmission direction D2, and the first transmission direction D1 and the second transmission direction D2 are different. Specifically, the direction of the first transmission direction D1 on the horizontal plane is opposite to the direction of the second transmission direction D2 on the horizontal plane. In addition, the spacing between each of the first openings O1 in the odd-numbered rows E1 is the same, the spacing between each of the first openings O1 in the even-numbered rows E2 is the same, the spacing between the first openings O1 in the odd-numbered rows E1 is the same as the spacing between the first openings O1 in the even-numbered rows E2, and the positions of the first openings O1 in the odd-numbered rows E1 and the positions of the first openings O1 in the even-numbered rows E2 are disposed in a staggered manner.

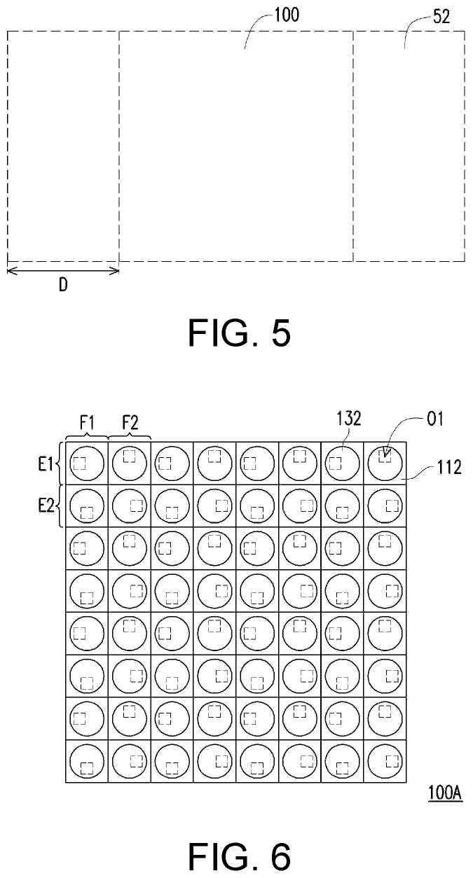

FIG. 5 is a schematic view of a sensing area of the fingerprint sensing module of FIG. 3. Referring to both FIG. 1 and FIG. 5, accordingly, with the design of the first openings O1 in the odd-numbered rows E1 and the first openings O1 in the even-numbered rows E2 in the first light shielding layer 140 disposed in a staggered manner, the sensing element 110 can receive the obliquely incident sensing light beam L2. That is, the area of the fingerprint sensing region 52 can be designed to be greater than the area of the projection of the fingerprint sensing module 100 on the display surface of the display panel 50, as the size of the area of the fingerprint sensing region 52 and the size of the area of the fingerprint sensing module 100 shown in FIG. 5. In a preferred embodiment, an angle of about 35 degrees is formed between the first transmission direction D1 and the second transmission direction D2 and the vertical direction, which can increase a width D (e.g., up to about 800 microns) of the fingerprint sensing region 52, as shown in FIG. 1 and FIG. 5. Compared with the general progressive inclined design, the spacing of the first openings O1 in the embodiment is equidistant, so the difficulty in fabrication can be reduced, the optical paths of different parts of the sensing light beams L2 can be kept the same, and further the optical path difference is prevented, so the good optical sensing effect can be maintained.

Referring to FIG. 2 again, note that the maximum sensing range of the fingerprint sensing module 100 in the embodiment can be adjusted by the size design of the structure. Specifically, the fingerprint sensing module 100 of the embodiment meets formula (1) and formula (2) as follows.

$$X = Δ X + \frac{H}{h} P ; \qquad ( 1 )$$

$$tan θ = \frac{X}{H} , \qquad ( 2 )$$

where

X is a single pixel width X in the fingerprint sensing module 100 or a pitch between two adjacent micro-lenses 132 (e.g., the distance from the center point of one micro-lens 132 to the center point of another micro-lens 132);

ΔX is the difference between the single pixel width X in the fingerprint sensing module 100 and a width Y of the micro-lens 132;

H is a distance H from the bottom surface of the micro-lens layer 130 to the bottom surface of a second light shielding layer 150;

h is a distance h from the sensing element 110 to the first light shielding layer 140;

P is a width P of the first opening O1 of the first light shielding layer 140;

θ is a central incident angle θ of the sensing light beam L2.

Therefore, according to the formulas, in different situations, the single pixel width X and the distance H can be adjusted to change the central incident angle 0 of the sensing light beam L2. The width P of the first opening O1 is designed to be within an acceptable and reasonable range of +/−5 μm of formula (1). That is,

$$P = \frac{h ( X - Δ X )}{H} \pm 5 µ m .$$

Moreover, a first critical light beam L31 and a second critical light beam L32 in the sensing light beam L2 incident to two opposite edges of a single micro-lens 132 are also illustrated in FIG. 2. In the embodiment, the design parameters of other structures can also be obtained by transmitting the first critical light beam L31 and the second critical light beam L32 into the light transmitting layer 120 to generate a refraction path. For the related formulas of the refraction and other structural parameters generated by transmitting the first critical light beam L31 and the second critical light beam L32 into the light transmitting layer 120, refer to formula (3) and formula (4) as follows.

$$tan θ 1 = \frac{X + ( \frac{Y}{2} )}{H} ; \qquad ( 3 )$$

$$tan θ 2 = \frac{X - ( \frac{Y}{2} )}{H} . \qquad ( 4 )$$

In addition, in the embodiment, the fingerprint sensing module 100 may further include the second light shielding layer 150 including multiple second openings O2 arranged in an array and disposed on an upper surface of the sensing element 110. The second openings O2 expose a part of the sensing units 112, respectively. In addition, the fingerprint sensing module 100 may further include a filter layer 160 disposed in the light transmitting layer 120. The filter layer 160 is an infrared cut filter, for example. However, in other embodiments, the filter layer 160 may also be a filter for filtering other visible light bands or invisible light bands.

FIG. 6 is a schematic top view of a fingerprint sensing module according to another embodiment of the invention. Referring to FIG. 6, a fingerprint sensing module 100A of the embodiment is similar to the fingerprint sensing module 100 shown in FIG. 3. The difference between the two is that in the embodiment, the first openings O1 in the odd-numbered rows E1 and odd-numbered columns F1 are located at first positions of the corresponding sensing unit 112, for example, shifted to the left in FIG. 6. The first openings O1 in the odd-numbered rows E1 and even-numbered columns F2 are located at second positions of the corresponding sensing unit 112, for example, shifted upward in FIG. 6. The first openings O1 in the even-numbered rows E2 and the odd-numbered columns F1 are located at third positions of the corresponding sensing unit 112, for example, shifted downward in FIG. 6. The first openings O1 in the even-numbered rows E2 and the even-numbered columns F2 are located at fourth positions of the corresponding sensing unit 112, for example, shifted to the right in FIG. 6. That is, the first openings O1 located at the first positions, the second positions, the third positions, and the fourth positions of the corresponding sensing unit 112 are shifted in different directions of the corresponding sensing unit 112, respectively.

Specifically, in the embodiment, the first openings O1 at the first positions are adapted to allow the sensing light beam L2 incident obliquely from left to right to be incident to the sensing unit 112. On the other hand, the first openings O1 located at the second positions are adapted to allow the sensing light beam L2 incident obliquely from top to bottom to be incident to the sensing unit 112 obliquely. By analogy, the first openings O1 at the third positions are adapted to allow the sensing light beam L2 incident obliquely from bottom to top to be incident to the sensing unit 112 obliquely. On the other hand, the first openings O1 located at the fourth positions are adapted to allow the sensing light beam L2 obliquely incident from right to left to be incident to the sensing unit 112.

That is, in the embodiment, the first openings O1 are repeatedly arranged in a 2×2 array. Compared with the fingerprint sensing module 100 in the embodiment of FIG. 3, the sensing light beam L2 of the embodiment can further include multiple third light beams and multiple fourth light beams according to the incident direction, and the third light beams are incident to the sensing unit in a third transmission direction, and the fourth light beams are incident to the sensing unit in a fourth transmission direction. The direction of the third transmission direction on the horizontal plane is opposite to the direction of the fourth transmission direction on the horizontal plane, and the direction of the third transmission direction on the horizontal plane and the direction of the fourth transmission direction on the horizontal plane are perpendicular to the direction of the first transmission direction on the horizontal plane and the direction of the second transmission direction on the horizontal plane.

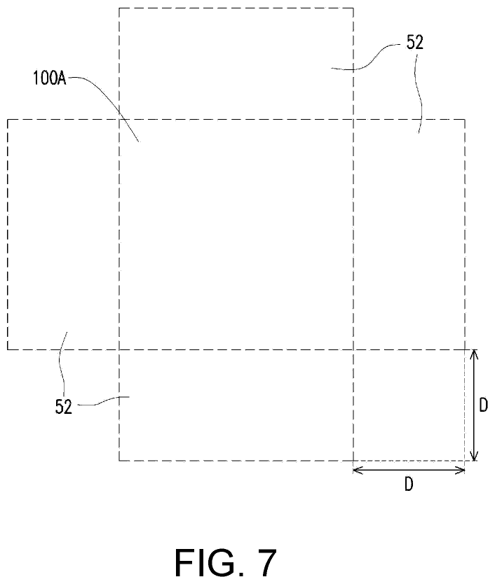

FIG. 7 is a schematic view of a sensing area of the fingerprint sensing module of FIG. 6. Referring to FIG. 7, accordingly, with the design of the four staggered positions of the first opening O1 of the first light shielding layer 140, the sensing element 110 can receive the oblique incident sensing light beam L2. That is, it is allowed that the area of the fingerprint sensing region 52 can be designed to be greater than the area of the projection of the fingerprint sensing module 100A on the display surface of the display panel 50 (refer to FIG. 1), as the fingerprint sensing region 52 shown in FIG. 7. In a preferred embodiment, an angle of about 35 degrees is formed between the first transmission direction to the fourth transmission direction and the vertical direction, so that the width D of the fingerprint sensing region 52 can be increased to about 800 microns, as shown in FIG. 7. In addition, compared with the general progressive inclined design, the spacing of the first openings O1 in the embodiment is all designed to be equidistant, so the difficulty in fabrication can be reduced, and the optical paths of different parts of the sensing light beam L2 can be kept the same, and further the optical path difference is prevented, so the good optical sensing effect can be maintained.

In summary, in the fingerprint sensing module and the electronic device of the invention, the first light shielding layer disposed in the light transmitting layer includes multiple first openings, and the positions of the first openings in the odd-numbered rows are different from the positions of the first openings in the even-numbered rows. Therefore, a part of the sensing light beam may be allowed to be incident to the sensing element in the first transmission direction, and another part of the sensing light beam can be incident to the sensing element in the second transmission direction. Accordingly, the sensing area may be increased, the difficulty in manufacturing may be reduced, and the optical path difference may be prevented to improve the good optical sensing quality.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A fingerprint sensing module, adapted for receiving a sensing light beam, comprising:
a sensing element, comprising a plurality of sensing units arranged in an array;
a light transmitting layer, disposed on the sensing element;
a micro-lens layer, disposed on the light transmitting layer and comprising a plurality of micro-lenses arranged in an array; and
a first light shielding layer, disposed in the light transmitting layer and comprising a plurality of first openings arranged in an array, wherein positions of the first openings in odd-numbered rows are the same, positions of the first openings in even-numbered rows are the same, the positions of the first openings in the odd-numbered rows are different from the positions of the first openings in the even-numbered rows, the sensing light beam comprises a plurality of first light beams and a plurality of second light beams, the first light beams are incident to at least a part of the sensing units in a first transmission direction, the second light beams are incident to at least another part of the sensing units in a second transmission direction, and the first transmission direction is different from the second transmission direction.

2. The fingerprint sensing module according to claim 1, wherein a direction of the first transmission direction on a horizontal plane is opposite to a direction of the second transmission direction on the horizontal plane.

3. The fingerprint sensing module according to claim 1, wherein the sensing light beam further comprises a plurality of third beams and a plurality of fourth beams, the third light beams are incident to at least another part of the sensing units in a third transmission direction, and the fourth light beams are incident to at least another part of the sensing units in a fourth transmission direction.

4. The fingerprint sensing module according to claim 3, wherein a direction of the third transmission direction on a horizontal plane is opposite to a direction of the fourth transmission direction on the horizontal plane, and the direction of the third transmission direction on the horizontal plane and the direction of the fourth transmission direction on the horizontal plane are perpendicular to a direction of the first transmission direction on the horizontal plane and a direction of the second transmission direction on the horizontal plane.

5. The fingerprint sensing module according to claim 1, wherein spacing of the first openings in the odd-numbered rows is the same, spacing of the first openings in the even-numbered rows is the same, the spacing of the first openings in the odd-numbered rows is the same as the spacing of the first openings in the even-numbered rows, and the positions of the first openings in the odd-numbered rows and the positions of the first openings in the even-numbered rows are disposed in a staggered manner.

6. The fingerprint sensing module according to claim 1, wherein the first openings are located at first positions in odd-numbered columns of the odd-numbered rows, the first openings are located at second positions in even-numbered columns of the odd-numbered rows, the first openings are located at third positions in the odd-numbered columns of the even-numbered rows, the first openings are located at fourth positions in the even-numbered columns of the even-numbered rows, and the first positions, the second positions, the third positions, and the fourth positions are different from one another.

7. The fingerprint sensing module according to claim 1, wherein positions of the sensing units are aligned with positions of the micro-lenses in a vertical direction.

8. The fingerprint sensing module according to claim 1, comprising:
a second light-shielding layer, comprising a plurality of second openings arranged in an array and disposed on the sensing element, wherein the second openings expose at least a part of the sensing units, respectively.

9. The fingerprint sensing module according to claim 1, comprising:
a filter layer, disposed on the light transmitting layer.

10. The fingerprint sensing module according to claim 1, wherein the fingerprint sensing module meets:
$$P = \frac{h ( X - Δ X )}{H} \pm 5 µ m ; and$$
$$tan θ = \frac{X}{H} ,$$
where X is a single pixel width in the fingerprint sensing module, ΔX is a difference between the single pixel width in the fingerprint sensing module and a width of one of the micro-lenses, H is a distance between a bottom surface of the micro-lens layer and a bottom surface of the second light shielding layer, h is a distance between the sensing element and the first light shielding layer, P is a width of one of the first openings of the first light shielding layer, and 0 is a central incident angle of the sensing light beam.

11. An electronic device, comprising:
a display panel, adapted to provide an illumination light beam to a finger to reflect a sensing light beam; and
a fingerprint sensing module, disposed below the display panel and adapted for sensing the sensing light beam reflected by the finger, wherein the fingerprint sensing module comprises:
a sensing element, comprising a plurality of sensing units arranged in an array;
a light transmitting layer, disposed on the sensing element;
a micro-lens layer, disposed on the light transmitting layer and comprising a plurality of micro-lenses arranged in an array; and
a first light shielding layer, disposed in the light transmitting layer and comprising a plurality of first openings arranged in an array, wherein positions of the first openings in odd-numbered rows are the same, positions of the first openings in even-numbered rows are the same, the positions of the first openings in the odd-numbered rows are different from the positions of the first openings in the even-numbered rows, the sensing light beam comprises a plurality of first light beams and a plurality of second light beams, the first light beams are incident to at least a part of the sensing units in a first transmission direction, the second light beams are incident to at least another part of the sensing units in a second transmission direction, and the first transmission direction is different from the second transmission direction.

12. The electronic device according to claim 11, wherein a direction of the first transmission direction on a horizontal plane is opposite to a direction of the second transmission direction on the horizontal plane.

13. The electronic device according to claim 11, wherein the sensing light beam further comprises a plurality of third beams and a plurality of fourth beams, the third light beams are incident to at least another part of the sensing units in a third transmission direction, and the fourth light beams are incident to at least another part of the sensing units in a fourth transmission direction.

14. The electronic device according to claim 13, wherein a direction of the third transmission direction on a horizontal plane is opposite to a direction of the fourth transmission direction on the horizontal plane, and the direction of the third transmission direction on the horizontal plane and the direction of the fourth transmission direction on the horizontal plane are perpendicular to a direction of the first transmission direction on the horizontal plane and a direction of the second transmission direction on the horizontal plane.

15. The electronic device according to claim 11, wherein spacing of the first openings in the odd-numbered rows is the same, spacing of the first openings in the even-numbered rows is the same, the spacing of the first openings in the odd-numbered rows is the same as the spacing of the first openings in the even-numbered rows, and the positions of the first openings in the odd-numbered rows and the positions of the first openings in the even-numbered rows are disposed in a staggered manner.

16. The electronic device according to claim 11, wherein the first openings are located at first positions in odd-numbered columns of the odd-numbered rows, the first openings are located at second positions in even-numbered columns of the odd-numbered rows, the first openings are located at third positions in the odd-numbered columns of the even-numbered rows, the first openings are located at fourth positions in the even-numbered columns of the even-numbered rows, and the first positions, the second positions, the third positions, and the fourth positions are different from one another.

17. The electronic device according to claim 11, wherein positions of the sensing units are aligned with positions of the micro-lenses in a vertical direction.

18. The electronic device according to claim 11, wherein the fingerprint sensing module comprises a second light shielding layer, the second light-shielding layer comprises a plurality of second openings arranged in an array and disposed on the sensing element, and the second openings expose at least a part of the sensing units, respectively.

19. The electronic device according to claim 11, comprising:
a filter layer, disposed on the light transmitting layer.

20. The electronic device according to claim 11, wherein the fingerprint sensing module meets:
$$P = \frac{h ( X - Δ X )}{H} \pm 5 µ m ; and$$
$$tan θ = \frac{X}{H} ,$$
where X is a single pixel width in the fingerprint sensing module, ΔX is a difference between the single pixel width in the fingerprint sensing module and a width of one of the micro-lenses, H is a distance between a bottom surface of the micro-lens layer and a bottom surface of the second light shielding layer, h is a distance between the sensing element and the first light shielding layer, P is a width of one of the first openings of the first light shielding layer, and θ is a central incident angle of the sensing light beam.
